(19) United States
(12) Patent Application Publication
(10) Pub. No.: US 2010/0146372 A1
(43) Pub. Date: Jun. 10, 2010

(54) DECODING OF SERIAL CONCATENATED CODES USING ERASURE PATTERNS

(76) Inventors: Martin Tomlinson, Devon (GB); Marcel Ambroze, Devon (GB)

Correspondence Address: WILLIAMS MULLEN, 222 CENTRAL PARK AVENUE, SUITE 1700, VIRGINIA BEACH, VA, 23462, US

(21) Appl. No.: 12/520,214

(22) PCT Filed: Dec. 14, 2007
(86) PCT No.: PCT/GB07/04812

§ 371 Date: Feb. 15, 2010

(30) Foreign Application Priority Data
Dec. 19, 2006 (GB) 0625228.2

(51) Int. Cl. H03M 13/45; G06F 11/10

(52) U.S. Cl. 714/780; 714/E11.032; 714/752

(57) ABSTRACT

A method of processing a received concatenated code codeword is disclosed, the concatenated code codeword comprising a plurality of inner code codewords and one or more outer code codewords, each inner code codeword comprising symbols, from each outer code codeword comprising one or more information symbols and one or more parity symbols, the parity symbols in each outer code codeword corresponding to the parity check equations of the outer code. The method comprises (i) decoding the received concatenated code codeword; (ii) erasing a subset of the received inner code codewords; and (iii) determining a replacement inner code codeword to replace each of the erased inner code codewords to provide a candidate concatenated code codeword. A preferred method further comprises (iv) erasing a further, different subset of the received inner code codewords; (v) determining further replacement inner code codewords to replace each of the thus erased inner code codewords to provide a further candidate concatenated code codeword; and (vi) determining the candidate concatenated code codeword having the highest correlation with the received vector of the decoded concatenated code codeword. A system for performing the method is also disclosed.

The present invention relates to a method for processing error correcting codes, in particular concatenated codes, and to a system for carrying out the same. The method and system of the present invention may be used to improve the efficiency of transmission of data. The method and system of the present invention find particular use in the transmission of data via soft decision communication channels, such a wireless, satellite or space communications, or for the soft decision storage channel.

The best error correcting codes having the highest Hamming distance for a given code rate can only be soft decision decoded in practice if the codes are short or have extreme code rates. Reference in this respect is made to F. J. MacWilliams and N. J. A. Sloane, The Theory of Error Correcting Codes, North Holland, 1977, and A. E. Brouwer, Bounds on the Minimum Distance of Linear Codes, (http://www.win.tue.nl/aeb/voorlincod.html). One such decoder, is the so-called Dorsch decoder, which for half rate codes is only effective in practice for codes whose length is less than approximately 180 bits. Details of the Dorsch decoder are described in B. G, Dorsch, A Decoding Algorithm for Binary Block Codes and J-ary Output Channels, IEEE Transactions Information Theory, Vol. IT-20, pp. 391-394, May 1974; M. P. C. Fossorier and S. Lin, Soft-decision decoding of linear block codes based upon ordered statistics, IEEE Transactions Information Theory, Vol. 41, pp. 1379-1396, September 1995; M. P. C. Fossorier and S. Lin, Computationally e□ent soft-decision decoding of linear block codes based upon ordered statistics, IEEE Transactions Information Theory, Vol. 42, pp. 738-750, May 1996; and M. Tomlinson, C. J Tjhai, M. Ambroze, and M. Z. Ahmed, Improved Error Correction Decoder using Ordered Symbol Reliabilities, UK Patent Application GB0637114.3.

Another type of decoder for linear codes is described by N. J. C. Lous, P. A. H. Bours, and H. C. A. van Tilborg, On maximum likelihood soft-decision decoding of binary linear codes, IEEE Transactions Information Theory, Vol. 39, pp. 197-203, January 1993.

Longer codes of similar code rate may be decoded using iterative decoding, as described in R. G. Gallager Low-Density Parity Check Codes. Cambridge Mass. M.I.T. Press, 1963; C. Berrou, P. Thitimajshima, and A. Glavieux. Near Shannon limit error correcting coding and decoding: turbo codes, Proc. IEEE International Conference on Communications, pages 10641070, Geneva, Switzerland, May 1993; R. M. Pyndiah. Near-optimum decoding of product codes: Block Turbo codes. IEEE Transactions Communications, vol 46, pp 1003-1010, August 1998; and J. Chen and M. P. C. Fossorier, Near Optimum Universal Belief Propagation Based Decoding of Low-Density Parity Check Codes, IEEE Trans. Comm, vol 50, No 3, pp 406-414, March 2002. However, such techniques need Low Density Parity Check (LDPC) codes or Turbo codes which suffer from non-convergence of the iterative decoder and produce error floors due to non convergence or due to low Hamming distance.

Accordingly, there is a need for an improved technique for encoding and decoding error correcting codes that improves transmission efficiency and the accuracy of the decoding of the received signal.

In a first aspect, the present invention provides a method of processing a received concatenated code codeword, the concatenated code codeword comprising a plurality of inner code codewords and one or more outer code codewords, each inner code codeword comprising one or more information or parity symbols, each outer code codeword comprising information and parity symbols from the inner code codewords, the method comprising:

(i) decoding the inner code codewords from the received concatenated code codeword;

(ii) erasing a subset of the received inner code codewords according to the correspondence between the symbols of each outer code codeword and the symbols of the inner code codewords; and

(iii) determining a replacement inner code codeword to replace each of the erased inner code codewords to provide a candidate concatenated code codeword.

In the method of the present invention, the concatenated code codeword is received from the communication of a transmitted signal or recovered from a storage medium as a received or recovered vector and is decoded in terms of detecting the inner code codewords and different sub-sets of these detected inner codewords are systematically erased using erasure patterns which correspond to the full erasure correcting capability of the outer code, and the erasure corrected, re-encoded inner code codewords are combined with the non erased, detected inner codewords to form candidate concatenated code codewords which are correlated with the stored received vector and after all of the total erasure patterns that are correctible by the outer code have been processed, the candidate concatenated code codeword with the highest correlation with the received vector is output from the decoder.

In one embodiment, not all of the total erasure patterns that correspond to the full erasure correcting capability of the outer code are used, for each received vector, but only those erasure patterns that correspond to those detected inner code codewords that have the smallest correlation values as determined from the detection of the inner code codewords and with the evaluation carried out in an order corresponding to the reliability of the detected inner code codewords. In one case, the method is carried out using a single erasure pattern, for example by erasing a single inner code codeword. The inner code codeword to be erased is thus selected as being that have the least correlation with the received or recovered vector.

In an alternative arrangement, the erasure of inner code codewords is repeated using a plurality of erasure patterns. Accordingly, in one embodiment the present invention provides a method of processing a received concatenated code codeword, the concatenated code codeword comprising a plurality of inner code codewords and one or more outer code codewords, each inner code codeword comprising one or more information symbols, each outer code codeword comprising one or more parity symbols, the parity symbols in the outer code codeword corresponding with symbols from each inner code codeword, the method comprising:

(i) decoding the received concatenated code codeword;

(ii) erasing a subset of the received inner code codewords according to the correspondence between the symbols of each outer code codeword and the symbols of the inner code codewords;

(iii) determining a replacement inner code codeword to replace each of the erased inner code codewords to provide a first candidate concatenated code codeword;

(iv) erasing a further, different subset of the received inner code codewords according to the said correspondence;

(v) determining further replacement inner code codewords to replace each of the thus erased inner code codewords to provide a further candidate concatenated code codeword; and

(vi) determining the candidate concatenated code codeword having the highest correlation with the received vector of the decoded concatenated code codeword.

As will be described hereinafter, in one embodiment all possible erasure patterns of inner code codewords are used to erase inner code codewords and provide a range of candidate concatenated code codewords, from which the decoded codeword is selected.

The method of the present invention can be used with relatively short powerful error correcting codes concatenated with good erasure correcting codes to produce a decoding performance that does not suffer from an error floor. Alternatively, it can be used with iteratively decoded inner codes so as increase the minimum Hamming distance and to eliminate the effects of stopping sets and trapping sets and thereby eradicate the cause of the error floor in iterative decoders.

The method of the present invention relies upon the use of a concatenated code codeword of a specific form, comprising a plurality of inner code codewords and one or more outer code codewords.

In a further aspect, the present invention therefore provides a concatenated code codeword comprising a plurality of inner code codewords and one or more outer code codewords, each inner code codeword comprising at least one symbol of the information and parity symbols of the outer code, each outer code codeword comprising symbols from all of the inner code codewords which include parity symbols of the outer code.

The concatenated code codeword comprises a plurality of inner code codewords. Each inner code codeword contains one or more symbols of the outer code. The data to be transmitted by way of the concatenated code codeword is comprised as the information symbols from all of the inner code codewords. In one embodiment, the inner code codewords each contain a plurality of symbols. All the symbols of a given inner code codeword may be information symbols of the outer code. Alternatively, the inner code codewords may comprise both data symbols and parity symbols of the outer code. The symbols from all of the inner code codewords combine together to form one or more codewords of the outer code, which comprise the concatenated code codeword.

The inner code codeword may comprise one or a plurality of symbols from the outer code. In the case that the inner code codeword comprises a single symbol, one or more inner code codewords will convey parity symbol information only from the outer code and hence will convey no data information. Should the inner code codeword comprise a plurality of symbols from the outer code one embodiment arranges that all inner code codewords contain information symbols from the outer code and convey data information. This latter embodiment is preferred, particularly where the symbols of the outer code comprise a large number of bits, as this provides the most efficient format of the concatenated code codeword for the transmission of data, while still allowing a high efficiency of decoding of the received signal.

An essential aspect of the concatenated code codeword is that each outer code codeword comprises one or more parity symbols that correspond to the symbols comprising each inner code codeword. Any suitable erasure correcting code may be used for the outer code but the well known, optimum, Reed Solomon erasure correcting codes are preferred. The simplest outer code is a single erasure correcting code which consists of a single parity symbol in the outer code codeword chosen such that the sum of all symbols taken from all of the inner code codewords, including the parity symbol, is zero. With the parity symbol comprising parity bits and information symbols comprising data bits, the sum of all bits corresponding to the same position in the symbol is zero

Symbols may consist of any suitable number of bits to provide the required efficiency of the decoding operation depending on the erasure correcting performance of the outer code. It is preferred that each symbol contains an equal number of bits but this is not essential. For the single erasure correcting outer code it is preferred that the parity symbol of the outer code codeword contains at least 12 bits.

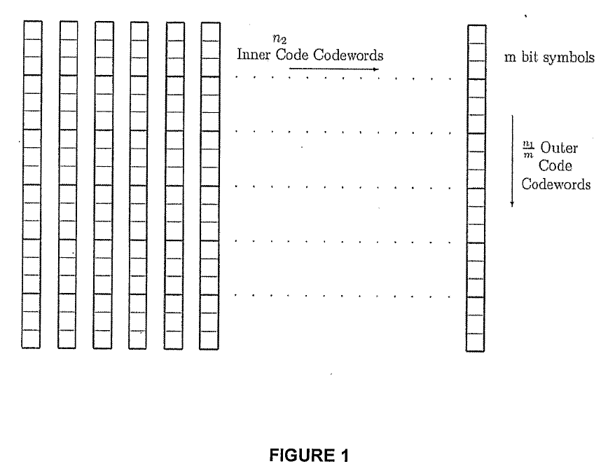

In one embodiment, The invention uses a concatenated code consisting of an inner (n1, k1, d1) code and an outer code (n2, k2, d2) to produce an overall code with parameters (n1×n2, k1×k2, d1×d2). The concatenated code is (n1×n2) symbols long, has (k1×k2) information symbols and minimum Hamming distance of (d1×d2). The format of the more usual case, where the inner code is binary, is shown in FIG. 1. The outer code is symbol based with m bits per symbol, as shown in FIG. 1, but a binary outer code may also be used. FIG. 1 shows the format of each concatenated codeword. Each concatenated codeword contains n2 inner code codewords. There are (n1/m) outer code codewords in each concatenated codeword.

In a still further aspect, the present invention provides a method of transmitting data, the method comprising compiling the data as bits in a concatenated code codeword comprising a plurality of inner code codewords and an outer code codeword, each inner code codeword comprising at least one symbol from the outer code and containing data and/or parity bits, the outer code codeword comprising at least one parity symbol and information symbols taken from the inner code codewords; and transmitting the concatenated code codeword.

As is standard practice for the transmission or storage of codeword symbols, the concatenated codeword symbols xᵢ, which are either non binary or binary, may be mapped to signal constellation points cᵢ. Details of such a mapping are known in the art, for example J. G. Proakis, ‘Digita/Communications’, McGraw-Hill, 1997.

Each codeword of the concatenated code x is typically transmitted over a general communications channel or stored on a storage medium as a mapped codeword \check{}c. The storage medium may be any suitable storage medium, examples of which are well known in the art. The mapped codeword is then received as the transmitted signal, or retrieved or recovered from the storage medium, using known techniques.

In the method of the present invention, the inner code codewords from the received or recovered concatenated code codeword are decoded. Suitable decoders for performing this function are well known in the art. One suitable decoder is a Dorsch decoder, as referred to hereinbefore. Aspects of the present invention will be described with reference to the decoding step being carried out by a Dorsch decoder. However, this is to be understood as being an example of just one suitable decoder and that other decoders may also be used.

The mapped codeword \check{}c is received, or recovered, and is denoted in the following as a received vector r. The Gaussian noise channel, the most common channel, is considered here. As is well known, for the Gaussian noise channel, the codeword most likely to have been transmitted is the codeword, denoted as \check{}x, which has the smallest squared Euclidean distance, D(\check{}x), between the mapped codeword \check{}c and the received vector, as expressed by the equation 1.

$$D ( \breve{x} ) = {\sum }_{i = 0 j = 0}^{{n}_{1} - 1 {n}_{2} - 1} {( {r}_{ij} - {\breve{c}}_{ij} )}^{2} \qquad ( 1 )$$

D(\check{}x)<D(x) for all other codewords x.

It is well known, that if all transmitted codewords have the same energy that equivalently \check{}x is the codeword, after mapping, which has the highest cross correlation since the codeword energy given by the following relation

$${\sum }_{i = 0 j = 0}^{{n}_{1} - 1 {n}_{2} - 1} {( {c}_{ij} )}^{2}$$

is a constant and the energy of the received vector, given by the following relation

$${\sum }_{i = 0 j = 0}^{{n}_{1} - 1 {n}_{2} - 1} {( {r}_{ij} )}^{2}$$

is an independent function, and not a function of the code. Accordingly the most likely concatenated code codeword to have been transmitted, has a correlation value Y(\check{}x) given by equation 2.

$$Y ( \breve{x} ) = {\sum }_{i = 0 j = 0}^{{n}_{1} - 1 {n}_{2} - 1} {r}_{ij} \times {\breve{c}}_{ij} \qquad ( 2 )$$

Y(\check{}x)>Y(x) for all other codewords x.

Without loss of generality of the present invention, the operation of the decoder in performing the method of the present invention of decoding the received signal may be described in terms of the cross correlation function of the inner code codewords with the received vector and the cross correlation function of the concatenated code codewords with the received vector. The cross correlation of each concatenated codeword may be expressed in terms of the correlation of the inner code codewords, of which the concatenated codeword is composed. Defining

$${Y}_{i} ( {\breve{x}}_{i} ) = {\sum }_{ j = 0}^{{n}_{1} - 1 } {r}_{ij} \times {\breve{c}}_{ij} \qquad ( 3 )$$

then

$$Y ( \breve{x} ) = {\sum }_{i = 0 j = 0}^{{n}_{1} - 1 {n}_{2} - 1} {r}_{ij} \times {\breve{c}}_{ij} = {\sum }_{i = 0}^{{n}_{2} - 1} {Y}_{i} ( {\breve{x}}_{i} ) \qquad ( 4 )$$

In the method of the present invention, the operation of the decoder is firstly to determine estimates of the most likely inner code codewords together with their associated correlation values by means of a suitable decoder, for example a Dorsch decoder, an iterative decoder or any other type of inner code decoder. The detected inner code codewords are denoted as ̂xᵢ and their respective correlation values are denoted as Yi(̂xᵢ). Hence

$${Y}_{i} ( {\hat{x}}_{i} ) = {\sum }_{j = 0}^{{n}_{1} - 1} {r}_{ij} \times {\hat{c}}_{ij} \qquad ( 5 )$$

In general, some of the detected inner codewords will be incorrect. The method of the present invention is applied to provide candidates for the correct inner code codewords, which are then assessed and the most likely candidate to be the inner code codeword transmitted or stored identified and used.

In the method of the present invention, erasure patterns are generated and these patterns are used to erase some of the detected inner code codewords. The operation of the invention is to systematically erase some or all of the information bits of combinations of the detected inner codewords that correspond to the full erasure correction capability of the outer code and that will result in concatenated code codewords after the erasures are corrected. These erased information bits are corrected by use of the parity symbol in the outer code codeword and the correlation between the parity symbol and the information symbols.

For each erased inner code codeword, a re-encoded inner codeword is formed from the parity check matrix or formed from the generator matrix of the inner code. These derived inner codewords are denoted as ~xᵢ. A candidate concatenated code codeword is constructed from these inner codewords and from the non-erased detected inner code codewords and the candidate concatenated code codeword is correlated against the received vector which is stored for this purpose. Following inner code codeword erasure correction, each constructed candidate concatenated code codeword is cross correlated against the stored received vector and the procedure repeated for every combination of inner code codeword erasures that corresponds to the full erasure correction capability of the outer code. After all erasure combinations have been evaluated the candidate concatenated code codeword with the highest cross correlation with the received vector is output by the method.

The pattern of erasures of the inner code codewords may be carried out and repeated until all possible patterns of the inner code codewords have been erased and new candidate concatenated code codewords generated. However, this may take a considerable time in the case of large codewords. In addition, this procedure will result in correct inner code codewords being erased and replaced, as well as inner code codewords that contain one or more errors.

Alternatively, therefore, only some but not all of the erasure patterns may be used, in particular the erasure patterns used are those having the lower correlation values with the received or recovered vector. In the simplest case, the method is carried out with just one erasure pattern being employed, using the pattern having the lowest correlation value with the received or recovered vector. Any number of erasure patterns between one and the maximum number of possible erasure patterns may be used, with the accuracy of the decoding method increasing and the time taken to decode decreasing as the number of erasure patterns used increases.

In this embodiment of the invention, the decoder complexity is traded off against decoder error rate by limiting the number of candidate concatenated code codeword correlations that are carried out. Instead of systematically erasing all (n₂/n₂−k₂) combinations of the inner code codewords only combinations of the least reliable inner code codewords are erased. The first step is to rank the inner code codewords in order of their reliability. The reliability of the detected inner code codewords is indicated by their correlation values. The inner code codewords correlation values are ranked in order of lowest correlation first and the ranking is used to determine and generate the erasures patterns. Correspondingly, the erasure patterns are generated in an order that corresponds to the least reliable inner code codewords being erased before more reliable inner code codewords. Decoding proceeds in ranked reliability order until either a fixed number of candidate concatenated code codewords have been correlated or until the concatenated code codeword correlation value exceeds a threshold, depending on the exit criteria of the decoder carrying out the method. The concatenated codeword with the highest correlation value is output from the decoder.

If the outer code codeword contains one or more information symbols in addition to the parity symbol correlated to the inner code codewords, then erasure of the outer code codeword may also be included in the pattern of erasures, in order to correct errors in the received information symbols of the outer code codeword.

It should be noted that only those erasure patterns are used which result in concatenated codewords from the concatenated code. Simply applying erasure patterns to detected inner code codewords and correcting these with the outer code will not necessarily result in a codeword from the concatenated code. A concatenated codeword from the concatenated code is ensured, for a particular erasure pattern, if the erasure pattern matches the full erasure capability of the outer code for that particular erasure pattern. The erasure pattern should be such that no more additional symbols from the n₂ symbols may be erased and corrected in addition to those corresponding to the erasure pattern. As the outer code has a minimum Hamming distance of d₂, up to d₂−1 erased symbols from an outer code codeword are guaranteed to be correctible by the outer code: However, for many erasure patterns the (n₂, k₂, d₂) outer code codeword can correct more than d₂−1 erased symbols up to a maximum of n₂−k₂ erased symbols. In the case where the outer code is from a broader family of codes known as Maximum Distance Separable (MDS) codes, all erasure patterns containing n₂₋k₂ erased symbols are correctible by the code and erasure correction will produce outer code codewords. Consequently if the outer code is an MDS code, the generation of erasure patterns is relatively simple and the erasure patterns used in the invention are all of the (n₂/n₂−k₂) combinations of n₂−k₂ inner code codewords and no others. If the outer code is not MDS, generation of erasure patterns is more complicated and the erasures combinations generator must generate only erasure patterns that cannot be appended with any additional, correctible erasures. For this reason the preferred arrangement is to use MDS codes such as the Reed-Solomon family of erasure correcting codes. If circumstances dictate the use of non-MDS codes, all correctible erasure patterns will need to be pre-calculated and stored in memory.

The inner code codewords may be any suitable code. One preferred case is where the inner code codewords are binary.

The outer code codeword may be any suitable code, but a preferred class of codes to use are the Reed Solomon (RS) codes, as these are known to be optimum codes from a broader family of codes known as Maximum Distance Separable (MDS) codes. The RS codes have length 2^{m}−1 and have m bit symbols with arithmetic from the Galois Field, GF(2^{m}). Any pattern of n₂−k₂ erasures may be corrected by the RS code and the minimum Hamming distance of the outer code is equal to n₂−k₂+1. For the case where the inner code is binary, each inner code codeword contains n₁/m, m bit symbols and each of these symbols is in a different outer code codeword as shown in FIG. 1.

As an example, the case is considered in which the outer code is a Reed Solomon (RS), (n₂, n₂−2, 3) MDS code capable of correcting any erasure pattern containing two erased symbols. Using this code in the method of the present invention, all of the information bits of the (n₂/2) erasure patterns containing exactly two inner codewords, ̂x_{α} and ̂x_{β}, are erased and corrected by means of the outer RS code using information from the detected inner code codewords ̂xᵢ, i≠α i≠β. New inner codewords ~x_{α} and ~x_{β} are bits from the detected inner code codewords encoded from these information bits, respectively. The corresponding cross correlation values for the replacement inner code codewords are obtained, Y_{α}(~x_{α}) and Y_{β}(~x_{β}). The cross correlation of the received vector with each candidate concatenated codeword is given by equation 6.

$$Y ( \hat{x} ) = {Y}_{α} ( {\tilde{x}}_{α} ) + {Y}_{β} ( {\tilde{x}}_{β} ) + {\sum }_{i = 0 i \neq α i \neq β}^{{n}_{2} - 1} {Y}_{i} ( {\hat{x}}_{i} ) \qquad ( 6 )$$

The correlation values obtained from using all (n₂/2) combinations of two erased inner code codewords from the n₂ detected, inner code codewords, are each determined and the concatenated codeword xₘₐₓ with the highest correlation value Y(xₘₐₓ) is output from the method.

For the general (n₂, k₂, d₂) optimum outer code case, the correlation values obtained from using (n₂/n₂−k₂) combinations of n₂−k₂ erasures from n₂ inner code codewords are determined and the concatenated codeword xₘₐₓ with the highest correlation value Y(xₘₐₓ) is output from the decoder.

In order to understand how the decoder applying the method of the present invention functions, it should be noted that if the detected inner codewords have been maximum likelihood decoded and contain errors, then

Y(\hat{x})≧Y(\hat{x}) (7)

but x is not a codeword of the concatenated code. Inner code decoding results in a collection of inner code codewords each (individually) having maximum correlation with the received vector but not necessarily satisfying the overall concatenated code constraint.

For the case in which the outer code is a Reed Solomon (RS), (n₂, n₂−2, 3) code, the concatenated code constraint is attained in the derivation of the codewords ~x_{α} and ~x_{β}. The derived codewords ~x_{α} and ~x_{β} will be incorrect, and usually a long way from the received vector, if the non erased inner codewords, from which they are derived, contain any errors. Correspondingly a relatively low correlation result for Y(x) will be obtained. The highest correlation result for Y(x) is obtained when the derived codewords ~x_{α} and ~x_{β} are correct because the inner codewords from which they are derived are also correct.

As described, the method of the present invention requires that the correlation of the each candidate codeword with the stored vector of the received or recovered concatenated code codeword. The correlation of the candidate codeword with the stored vector may involve the entire codeword, that is all inner and outer code codewords. Again, in the case of a large concatenated code codeword containing a large number of inner code codewords, this may take some time and reduce the speed of decoding.

In an alternative embodiment of the method of the invention it is not necessary to compute the cross correlation of the entire concatenated codeword each time a new candidate codeword is generated. As indicated by equation 6, the correlation of the candidate concatenated codeword is equal to the sum of the correlation values of a sub-set of the detected inner code codewords plus the correlation values of the re-encoded inner code codewords. Whilst the correlation values of the replacement inner code codewords need to be calculated each time, there is no need to recalculate any of the correlation values of the detected inner code codewords that have not been erased and re-encoded. Rather, these can be made available as outputs from the decoder decoding the inner code codewords. The correlation values of the detected inner code codewords are output from the inner code decoder. The sub-set of which inner code correlation values are to be used in the concatenated code codeword correlation is selected according to the output of the erasures combination generator. The information symbols of the erased inner code codewords are corrected and the re-encoded inner code codewords input to the concatenated code codeword correlator. The correlation values obtained from correlating the replacement inner code codewords with the received vector are added to the sub-set of detected inner code correlation values and the resulting candidate concatenated code codeword correlation value is stored. As before, after some or all inner code codeword erasure combinations have been evaluated, the candidate concatenated code codeword with the highest correlation value is output from the decoder.

As noted hereinbefore, the parity symbols and the information symbols of each outer code codeword are contained in the inner codewords. As also noted, weighted parity and information symbols of the outer code sum to zero according to the parity check equations of the outer code. In one embodiment, each inner code codeword contains one or more symbols which are information or parity symbols from each outer code codeword. Each outer code codeword, comprises a parity symbol such that the weighted sum of the parity and information symbols of all the inner code codewords in the concatenated codes sums to zero.

In such a case, the method of the present invention is one in which a concatenated code codeword is transmitted, or stored in which the received vector is decoded in terms of detecting the inner code codewords each of which comprises multiple symbols from an outer code and in which the outer code parity symbol sum from each inner code codeword is systematically erased using erasure patterns which correspond to the full erasure correcting capability of the outer code, and inner code codewords which possess parity symbol sums equal to the corrected erasures are combined with the non erased, detected inner codewords to form candidate concatenated code codewords which are correlated with the stored received vector and after all of the total erasure patterns that are correctible by the outer code have been processed, the candidate concatenated code codeword with the highest correlation with the received vector is output from the decoder.

As noted hereinbefore, it is not necessary that all the possible erasure patterns of the inner code codewords are erased, but rather that a selection of less than all of the total erasure patterns that correspond to the full erasure correcting capability of the outer code are used, for each received vector. In particular, only those erasure patterns that correspond to those parity symbol sums of the detected inner code codewords that have the smallest correlation values as determined from the detection of the inner code codewords are used to erase the inner code codewords. In this case, the evaluation of the replacement inner code codewords may be carried out in ascending order corresponding to the reliability of the detected inner code codewords.

Finally, it may be the case that the length of the inner codes is not equal to an integral multiple of the outer code symbols. In such a case, the inner code codewords may be extended by the addition of one or more dummy zero bits to the received inner code codewords, in order to calculate the outer code parity sum for that codeword. The addition of a zero bit will not alter the values of the parity sums contained in the inner and outer code codewords, but will allow the calculation based on the sums to be carried out.

In a further aspect, the present invention provides a system for transmitting or storing information, the system comprising means to encode the information in a concatenated code codeword, the concatenated code codeword comprising a plurality of inner code codewords and one or more outer code codewords, each inner code codeword comprising at least one symbol, each outer code codeword comprising one or more parity symbols contained in the symbols supplied from the inner code codewords.

A still further aspect of the present invention provides a system for decoding a concatenated code codeword, the concatenated code codeword comprising a plurality of inner code codewords and one or more outer code codewords, the inner code codewords comprising one or more information symbols and/or one or more parity symbols, each outer code codeword comprising symbols from the symbols of the inner code codewords, the system comprising:

(i) means for decoding the received concatenated code codeword;

(ii) means for erasing a subset of the received inner code codewords according to the correspondence between the parity and information symbols of each outer code codeword contained in each inner code codeword; and

(iii) means for generating a replacement inner code codeword to replace each of the erased inner code codewords to provide a candidate concatenated code codeword.

In a preferred embodiment, the system comprises:

(i) means for decoding the received concatenated code codeword;

(ii) means for erasing a subset of the received inner code codewords according to the correspondence between the parity and information symbols of each outer code codeword contained in each inner code codeword;

(iii) means for generating a replacement inner code codeword to replace each of the erased inner code codewords to provide a first candidate concatenated code codeword;

(iv) means for erasing a further, different subset of the received inner code codewords according to the said correlation;

(v) means for generating further replacement inner code codewords to replace each of the thus erased inner code codewords to provide a further candidate concatenated code codeword; and

(vi) means for determining the candidate concatenated code codeword having the highest correlation with the decoded concatenated code codeword.

Embodiments of the present invention will now be described, for illustrative purposes only, having reference to the accompanying figures, in which:

FIG. 1 is a diagrammatic representation of a concatenated code codeword according to the present invention;

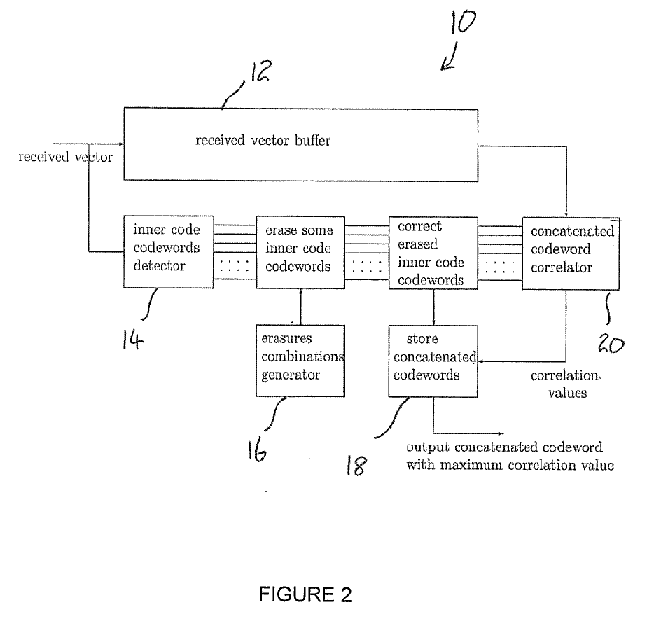

FIG. 2 is a diagrammatic representation of a first decoder system according to a first embodiment of the present invention;

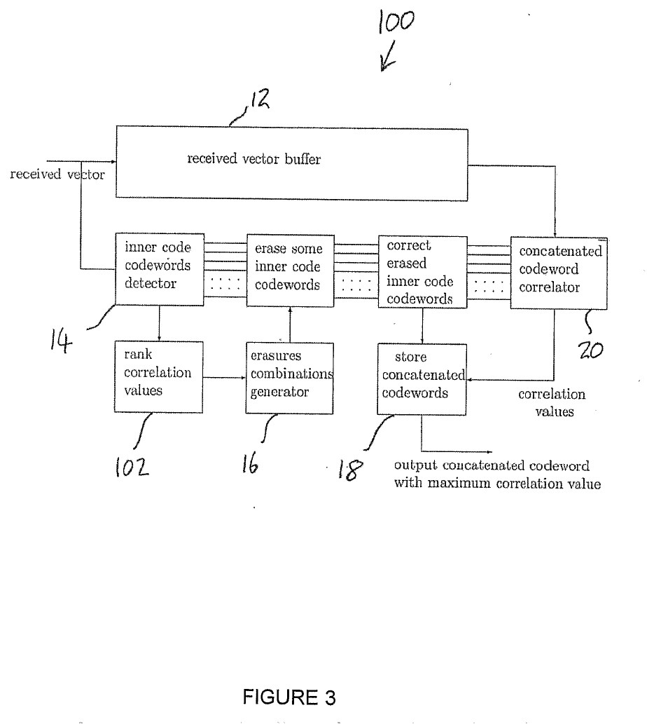

FIG. 3 is a diagrammatic representation of a second decoder system according to a second embodiment of the present invention;

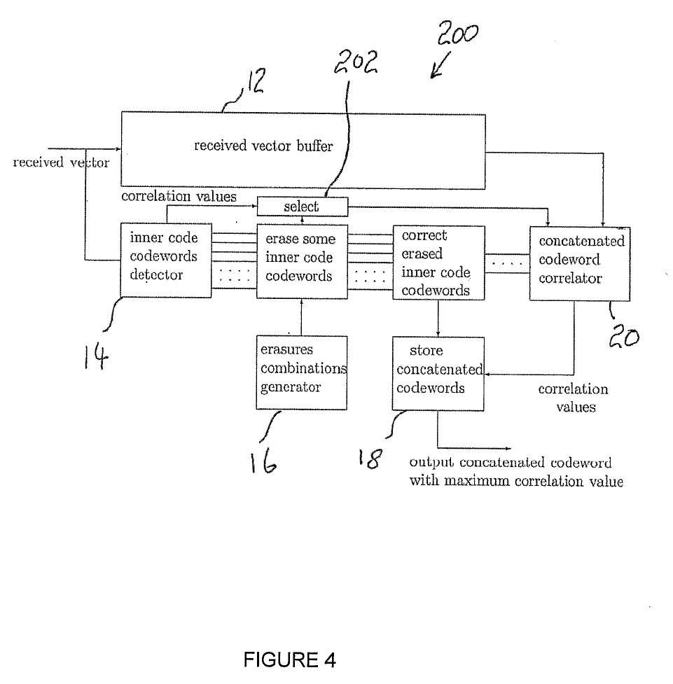

FIG. 4 is a diagrammatic representation of a third decoder system according to a third embodiment of the present invention;

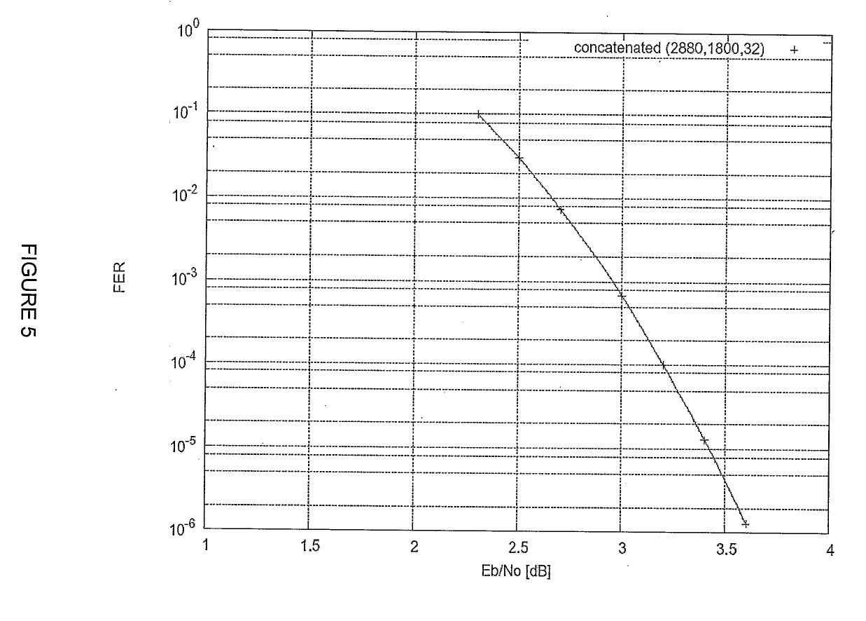

FIG. 5 is a graph of the performance of a first embodiment of the method of the present invention in decoding a concatenated code codeword; and

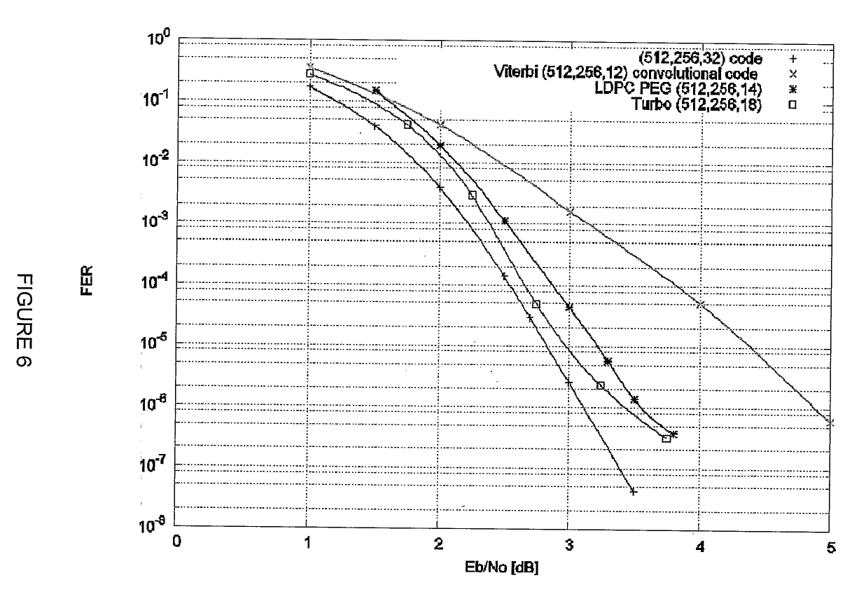

FIG. 6 is a graph of the performance of a second embodiment of the method of the present invention in decoding a concatenated code codeword.

Referring to FIG. 2, a system for performing the method of the present invention to process and decode a received or recovered concatenated code is shown. The system, generally indicated as 10, comprises a received vector buffer 12, in which the vector of the concatenated code codeword, as received as a transmitted signal or recovered from a storage device, is stored. The system further comprises a detector 14 for identifying the inner code codewords of the received vector. An erasure combinations generator 16 determines appropriate erasure patterns to be applied to the inner code codewords identified by the detector 14, on the basis of which a selection of one or more inner code codewords are erased. Corrected inner code codewords are generated, in accordance with the correspondence between the inner code codeword symbols and the information and parity symbols of each outer code codeword. The thus generated inner code codewords are used to generate a candidate replacement concatenated code codeword, which is stored in a storage device 18. Each candidate concatenated code codeword is compared with and correlated against the received vector stored in the buffer 12 by a correlator 20. The result of the correlation is output from the correlator 20 and used to identify the candidate concatenated codeword having the maximum correlation with the received vector. This candidate is output from the system as the decoded concatenated code codeword.

Referring to FIG. 3, there is shown a diagrammatic representation of an alternative embodiment of the system of the present invention. The components of the system of FIG. 3 common to the system shown in FIG. 2 and described hereinbefore are identified using the same reference numerals. The differences between the system of FIGS. 2 and 3 will be described.

In the system of FIG. 3, generally indicated as 100, comprises a means 102 to rank the inner code codewords identified by the detector 14 in the received vector. This ranking is achieved by mapping and comparing the identified inner code codewords with the inner code codewords in the received vector. The ranking of the inner code codewords achieved in this manner is input to the erasures combinations generator 16 and combinations of erasures of the inner code codewords produced that include the least reliable inner code codewords. These may be identified as being the least reliable, for example by comparison with thresholds preset or introduced into the system. The remainder of the system and its function are as for the system of FIG. 2, described hereinbefore.

It will be appreciated that the inclusion of the means 102 for ranking the inner code codewords identifies the portions of the received vector containing the highest likely error rate. The system operates to concentrate the correction of these errors, while reducing the time taken to decode the received vector by not erasing and restoring the inner code codewords that have a high indicated level of reliability.

Turning to FIG. 4, there is shown a diagrammatic representation of a further alternative embodiment of the system of the present invention. The components of the system of FIG. 4 common to the system of FIG. 2 are described hereinbefore and identified using the same reference numerals. The differences between the system of FIG. 2 and FIG. 4 will be described.

In the system of FIG. 4, generally indicated as 200, the correlation values of the inner code codewords identified by the detector 14 are input to a selector 202. The selector 202 identifies those inner code codewords for which correlations have been obtained in the decoder and outputs this information to the correlator 20, which uses this information to identify and determine correlations only for those inner code codewords that have not been correlated earlier in the system. The remainder of the operation of the system 202 is as described above in connection to FIG. 2. The system of FIG. 4 again provides an increased efficiency, by not requiring the decoder 20 to repeat operations for which the system already has data.

The present invention will now be further illustrated by way of the following specific examples.

### EXAMPLES

### Example 1

In this example there is only one outer code codeword consisting of 4 symbols each of length 17 bits. A concatenated code codeword is constructed as follows:

The structure of the outer code is the single overall parity check code of length 4, and is a (4, 3, 2) code whose minimum Hamming distance is 2. In this example, the inner code is the (17, 9, 5) quadratic residue cyclic code with parity check polynomial 1+x+x³+x⁶+x⁸+x⁹. The minimum Hamming distance of the overall concatenated code is 5×2=10 and forms a (68, 27, 10) code. Each inner code codeword is a single symbol from the outer code. The first three inner code codewords convey data, the fourth inner code codeword is a parity symbol of the outer code and conveys no data information.

A single concatenated codeword is considered consisting of the four inner codewords:

$$\begin{matrix}0 & 1 & 0 & 1 & 0 & 1 & 0 & 1 & 0 & 0 & 0 & 0 & 1 & 1 & 0 & 0 & 0 \\ 1 & 0 & 1 & 0 & 0 & 1 & 1 & 0 & 1 & 1 & 0 & 1 & 1 & 0 & 0 & 1 & 0 \\ 1 & 0 & 0 & 1 & 0 & 0 & 0 & 1 & 0 & 0 & 1 & 0 & 1 & 1 & 1 & 1 & 0 \\ 0 & 1 & 1 & 0 & 0 & 0 & 1 & 0 & 1 & 1 & 1 & 1 & 1 & 0 & 1 & 0 & 0\end{matrix}$$

It will be noticed that the fourth inner code codeword when added bit wise to the other three inner code codewords produces a parity sum of zero. It is also an inner code codeword satisfying the inner code parity check polynomial 1+x+x³+x⁶+x⁸+X⁹.

Before transmission the 0's are mapped to 1's and the 1's are mapped to −1's and transmitted over a Gaussian noise channel. Operating at an (Eb/Nₒ) of 3 dB the codewords are received as the received vector set out in Table 1.

TABLE 1
Received vector corresponding to transmitted concatenated code codeword

| | | | | | | | | | | | | | | | | |
|---|---|---|---|---|---|---|---|---|---|---|---|---|---|---|---|---|
| 0.5 | −1.9 | 0.9 | −0.8 | 0.9 | −1.6 | 0.3 | −0.4 | 1.8 | 0.3 | 0.6 | 1.2 | −0.1 | −0.7 | 2.3 | 0.3 | −0.3 |
| −1.1 | 1.2 | −1.4 | 1.4 | 0.7 | −0.9 | −1.7 | 1.1 | 0.9 | −1.8 | −0.5 | −0.6 | 0.0 | 0.5 | 1.1 | −1.3 | 1.2 |
| −0.1 | −0.3 | 0.4 | −0.8 | 1.5 | 0.6 | 1.2 | −0.8 | −0.5 | 1.5 | −0.6 | 2.0 | −0.8 | −1.2 | 0.0 | 0.0 | 0.7 |
| 0.7 | −2.3 | −2.2 | 1.8 | 0.9 | 0.4 | −0.5 | 1.4 | −0.7 | −1.0 | −0.9 | −0.5 | −1.1 | 0.2 | −0.6 | 1.9 | 1.7 |

Each row of Table 1 corresponds to a transmitted inner code codeword.

In this example, the inner code codewords are each maximum likelihood decoded using a Dorsch decoder to produce the most likely inner code codewords, as follows:

$$\begin{matrix}0 & 1 & 0 & 1 & 0 & 1 & 0 & 1 & 0 & 0 & 0 & 0 & 1 & 1 & 0 & 0 & 0 \\ 1 & 0 & 1 & 0 & 0 & 1 & 1 & 0 & 1 & 1 & 0 & 1 & 1 & 0 & 0 & 1 & 0 \\ 1 & 1 & 1 & 1 & 0 & 0 & 0 & 1 & 1 & 0 & 1 & 0 & 1 & 1 & 0 & 0 & 0 \\ 0 & 1 & 1 & 0 & 0 & 0 & 1 & 0 & 1 & 1 & 1 & 1 & 1 & 0 & 1 & 0 & 0\end{matrix}$$

It will be noticed by comparison with the transmitted concatenated codeword, that these inner code codewords are all correct except for the third inner code codeword. The correlation of this codeword (when mapped) with the received vector is 12.87 and higher than that of the transmitted (the correct) codeword which is 12.12. Thus, on the basis of this initial check, the detected third inner code codeword is considered more likely to have been transmitted than the correct inner code codeword.

In the next step each of the inner code codewords is systematically erased and derived from the other detected inner code codewords using the parity check matrix of the outer code. In this example, the outer code is a single parity symbol containing the erasure correcting code and so the inner code codewords are systematically erased one codeword at a time and a new inner code codeword derived from the other three detected inner code codewords by using the set of overall parity check equations correlating the inner code codewords with the parity symbol of the outer code codeword, one for each bit position.

The first inner code codeword is erased and a replacement code codeword generated. Carrying out the overall parity checks for each bit position for the first inner code codeword produces the following replacement codeword:

0 0 1 1 0 1 0 1 1 0 0 0 1 1 1 1 0

Together with the other three, non erased, detected inner code codewords, a new concatenated code-word is constructed. This new concatenated codeword is correlated with the received vector which produces a correlation value of 47.54.

The procedure is repeated and this time the second inner code codeword is erased. The second inner code codeword, is replaced with the following codeword calculated using the parity check equation for each bit:

1 1 0 0 0 1 1 0 0 1 0 1 1 0 1 0 0

Using the original detected inner code codewords for the first, third and fourth codewords with this replacement codeword for the second inner code codeword produces a new concatenated codeword which is correlated with the received vector to produce a correlation value of 54.26.

The third inner code codeword, is erased and replaced with the following generated replacement codeword:

1 0 0 1 0 0 0 1 0 0 1 0 1 1 1 1 0

Using the original detected inner code codewords for the first, second and fourth codewords with this replacement codeword for the third inner code codeword produces a new concatenated codeword which is correlated with the received vector to produce a correlation value of 61.88.

Finally, the fourth inner code codeword, is replaced in similar manner with the following replacement codeword:

0 0 0 0 0 0 1 0 0 1 1 1 1 0 0 1 0

Using the original detected inner code codewords for the first, second and third codewords with the above replacement codeword for the fourth inner code codeword produces a new concatenated codeword which is correlated with the received vector to produce a correlation value of 46.94.

Of the four candidate concatenated code codeword correlations, the highest correlation value is 61.88 which is produced with the third inner code codeword replaced and the corresponding concatenated codeword is:

$$\begin{matrix}0 & 1 & 0 & 1 & 0 & 1 & 0 & 1 & 0 & 0 & 0 & 0 & 1 & 1 & 0 & 0 & 0 \\ 1 & 0 & 1 & 0 & 0 & 1 & 1 & 0 & 1 & 1 & 0 & 1 & 1 & 0 & 0 & 1 & 0 \\ 1 & 0 & 0 & 1 & 0 & 0 & 0 & 1 & 0 & 0 & 1 & 0 & 1 & 1 & 1 & 1 & 0 \\ 0 & 1 & 1 & 0 & 0 & 0 & 1 & 0 & 1 & 1 & 1 & 1 & 1 & 0 & 1 & 0 & 0\end{matrix}$$

This concatenated codeword is output from the decoder and it will be seen that this codeword is correct and corresponds to the transmitted concatenated code codeword.

It is to be noted that this correct decoded codeword is generated by the method, despite the initial indication of the correlation of the third received inner code codeword as being particularly high, indicating that no error is present.

As described in the preceding general description, one embodiment of the method requires that only some of the possible replacement concatenated code codewords are correlated with the received vector, in order to improve the overall speed and efficiency of the method and system. Thus, considering the numerical example above, the inner code correlation values are found to be respectively 15.18, 15.16, 12.11 and 19.43. After ranking in order of increasing reliability, the order of the inner code codewords in terms of increasing reliability is 3, 2, 1, 4. Erasing, and replacing the third inner codeword first, in this example, to generate a candidate replacement concatenated code codeword immediately produces the correct concatenated codeword.

### Example 2

An example of the decoder error performance achieved by the method of the present invention as a function of the ratio of the energy per information bit E_{b} and the single sided noise spectral density Nₒ, is shown in FIG. 5 for the white Gaussian noise channel and using a (2880, 1800, 32) concatenated code.

The inner code consists of a rate 2/3, (180, 120, 16) code and the outer code is a rate 15/16, (16, 15, 2) single parity check code. For each concatenated codeword there is a single outer code codeword consisting of 16 symbols and each symbol is 180 bits long. The inner code is decoded using a Dorsch decoder which is set to correlate 10⁶ codewords in the detection of each inner code codeword for each received vector. All 16 combinations of single inner code codeword erasures out of 16 detected inner code codewords are evaluated for each received vector. Thus, following detection of the 16 inner code codewords for each received vector, there are 16 candidate concatenated codewords correlated with the received vector, and the concatenated codeword with the largest correlation value is output. Analysis of the concatenated codewords decoded in error reveals that these are all the result of at least two inner code codewords detected in error by the Dorsch decoder and therefore beyond the erasure correcting range of the E_{b}

outer code.

As shown in FIG. 5 the overall performance is such that at an E_{b}/Nₒ ratio of 3.2 dB the output codeword error rate of the concatenated code is approximately 10⁻⁴. There is no trace of an error floor which is to be expected as the concatenated code has a minimum Hamming distance of 32 and the invention achieves near maximum likelihood decoding of this concatenated code.

### Example 3

In this example, the outer code is the single overall parity check code of length 4 symbols, and is a (4, 3, 2) code whose minimum Hamming distance is 2. In this example, the inner code is the extended (18, 9, 6) quadratic residue cyclic code with a parity check matrix given by cyclic shifts of the parity check polynomial 1+x+x³+x⁶+x⁸+x⁹, plus an overall parity check. The minimum Hamming distance of the overall concatenated code is 6×2=12 and forms a (72, 27, 12) code. Each concatenated codeword consists of a single outer code codeword of 4 symbols with each symbol being an inner code codeword of length 18 bits.

A single concatenated codeword is considered consisting of the four inner codewords as follows:

$$\begin{matrix}0 & 1 & 0 & 1 & 0 & 1 & 0 & 1 & 0 & 0 & 0 & 0 & 1 & 1 & 0 & 0 & 0 & 0 \\ 1 & 0 & 1 & 0 & 0 & 1 & 1 & 0 & 1 & 1 & 0 & 1 & 1 & 0 & 0 & 1 & 0 & 1 \\ 1 & 0 & 0 & 1 & 0 & 0 & 0 & 1 & 0 & 0 & 1 & 0 & 1 & 1 & 1 & 1 & 0 & 0 \\ 0 & 1 & 1 & 0 & 0 & 0 & 1 & 0 & 1 & 1 & 1 & 1 & 1 & 0 & 1 & 0 & 0 & 1\end{matrix}$$

Before transmission the 0's are mapped to 1's and the 1's are mapped to −1's and transmitted over a Gaussian noise channel. Operating at an Eb/No of 3 dB the codewords are received as the noisy received vector set out in Table 2 below.

TABLE 2
Received vector corresponding to transmitted concatenated code codeword

| | | | | | | | | | | | | | | | | | |
|---|---|---|---|---|---|---|---|---|---|---|---|---|---|---|---|---|---|
| 0.5 | −1.9 | 0.9 | −0.8 | 0.9 | −1.6 | 0.3 | −0.4 | 1.8 | 0.3 | 0.6 | 1.2 | −0.1 | −0.7 | 2.3 | 0.3 | −0.3 | 0.8 |
| −1.1 | 1.2 | −1.4 | 1.4 | 0.7 | −0.9 | −1.7 | 1.1 | 0.9 | −1.8 | −0.5 | −0.6 | 0.0 | 0.5 | 1.1 | −1.3 | 1.2 | −0.3 |
| −0.1 | −0.3 | 0.4 | −0.8 | 1.5 | 0.6 | 1.2 | −0.8 | −0.5 | 1.5 | −0.6 | 2.0 | −0.8 | −1.2 | 0.0 | 0.0 | 0.7 | −0.1 |
| 0.7 | −2.3 | −2.2 | 1.8 | 0.9 | 0.4 | −0.5 | 1.4 | −0.7 | −1.0 | −0.9 | −0.5 | −1.1 | 0.2 | −0.6 | 1.9 | 1.7 | −0.2 |

Each row of Table 2 corresponds to a transmitted inner code codeword.

In this example, the inner code codewords are each maximum likelihood decoded using a Dorsch decoder to produce the most likely inner code codewords as follows:

$$\begin{matrix}0 & 1 & 0 & 1 & 0 & 1 & 0 & 1 & 0 & 0 & 0 & 0 & 1 & 1 & 0 & 0 & 0 & 0 \\ 1 & 0 & 1 & 0 & 0 & 1 & 1 & 0 & 1 & 1 & 0 & 1 & 1 & 0 & 0 & 1 & 0 & 1 \\ 1 & 1 & 1 & 1 & 0 & 0 & 0 & 1 & 1 & 0 & 1 & 0 & 1 & 1 & 0 & 0 & 0 & 1 \\ 0 & 1 & 1 & 0 & 0 & 0 & 1 & 0 & 1 & 1 & 1 & 1 & 1 & 0 & 1 & 0 & 0 & 1\end{matrix}$$

It will be noticed by comparison with the transmitted concatenated codeword, that these inner code codewords are all correct except for the third inner code codeword. The correlation of this codeword (when mapped) with the received vector is 12.3 and higher than that of the transmitted (the correct) codeword which is 11.3. Thus the detected third inner code codeword would generally be considered more likely to have been transmitted than the correct inner code codeword, despite the error.

In the next step the inner code codewords are systematically erased and derived from the other detected inner code codewords using the parity check matrix of the outer code, as in Example 1. In this example, the outer code is a single erasure correcting code and so the inner code codewords are systematically erased one codeword at a time and a new inner code codeword derived from the other three detected inner code codewords by using the set of overall parity check equations, one for each bit position.

Carrying out the erasure overall parity checks for each bit position for the first inner code codeword produces the following replacement inner code codeword:

0 0 1 1 0 1 0 1 1 0 0 0 1 1 1 1 0 1

Together with the other three, non erased, detected inner code codewords, a new concatenated codeword is constructed. This new concatenated codeword is correlated with the received vector which produces a correlation value of 45.3.

The procedure is repeated and this time the second inner code codeword is erased. The second inner code codeword, is replaced with the following codeword calculated using the parity check equation for each bit:

1 1 0 0 0 1 1 0 0 1 0 1 1 0 1 0 0

Using the original detected inner code codewords for the first, third and fourth codewords with this replacement codeword for the second inner code codeword produces a new concatenated codeword which is correlated with the received vector to produce a correlation value of 52.5.

The third inner code codeword is replaced in similar manner with the following:

1 0 0 1 0 0 0 1 0 0 1 0 1 1 1 1 0 0

Using the original detected inner code codewords for the first, second and fourth codewords with this replacement codeword for the third inner code codeword produces a new concatenated codeword which is correlated with the received vector to produce a correlation value of 60.3.

Finally, the fourth inner code codeword, is replaced in similar manner with the following code:

0 0 0 0 0 0 1 0 0 1 1 1 1 0 0 1 0 0

Using the original detected inner code codewords for the first, second and third codewords with the above replacement codeword for the fourth inner code codeword produces a new concatenated codeword which is correlated with the received vector to produce a correlation value of 45.5.

Of the four candidate concatenated code codeword correlations, the highest correlation value is 60.3 which is produced with the third inner code codeword replaced and the corresponding complete concatenated codeword is as follows:

$$\begin{matrix}0 & 1 & 0 & 1 & 0 & 1 & 0 & 1 & 0 & 0 & 0 & 0 & 1 & 1 & 0 & 0 & 0 & 0 \\ 1 & 0 & 1 & 0 & 0 & 1 & 1 & 0 & 1 & 1 & 0 & 1 & 1 & 0 & 0 & 1 & 0 & 1 \\ 1 & 0 & 0 & 1 & 0 & 0 & 0 & 1 & 0 & 0 & 1 & 0 & 1 & 1 & 1 & 1 & 0 & 0 \\ 0 & 1 & 1 & 0 & 0 & 0 & 1 & 0 & 1 & 1 & 1 & 1 & 1 & 0 & 1 & 0 & 0 & 1\end{matrix}$$

This concatenated codeword is output from the decoder and it will be seen that this codeword is correct and corresponds to the transmitted concatenated code codeword.

### Example 4

This example demonstrates a further embodiment of the invention, in which the outer code consists of symbols which are a sub-multiple of the inner code so that each inner code codeword consists of several symbols of the outer code and not simply one symbol. This reduces the parity bits overhead associated with the outer code.

The same inner code as in Example 3 is used, with the extended (18, 9, 6) quadratic residue cyclic code with a parity check matrix given by cyclic shifts of the parity check polynomial 1+x+x³+x⁶+x⁸+x⁹ plus an overall parity. The outer code uses 6 bit symbols with a single symbol parity check from a (12, 11, 2) code. This time a (72, 30, 12) concatenated code is produced from the combination of the four inner code codewords, each contributing 3 symbols to the outer code codeword of length 12 symbols.

The parity check bits for the outer code are represented as x and the parity check bits for the inner code are shown as y in the concatenated codeword as follows:

$$\begin{matrix}0 & 1 & 0 & 1 & 0 & 1 & 0 & 1 & 0 & y & y & y & y & y & y & y & y & y \\ 1 & 0 & 1 & 0 & 0 & 1 & 1 & 0 & 1 & y & y & y & y & y & y & y & y & y \\ 1 & 0 & 0 & 1 & 0 & 0 & 0 & 1 & 0 & y & y & y & y & y & y & y & y & y \\ x & x & x & x & x & x & 1 & 0 & 1 & y & y & y & y & y & y & y & y & y\end{matrix}$$

The first three inner code codewords are encoded independently and convey 9 information bits each. The last inner code codeword conveys 3 information bits. For each inner code codeword the 6 bit parity bit sum contributed to the outer code is calculated and is shown below (commas have been inserted to delimit the inner code 6 bit symbols)

$$\begin{matrix}0 & 1 & 0 & 1 & 0 & 1 , & 0 & 1 & 0 & 0 & 0 & 0 , & 1 & 1 & 0 & 0 & 0 & 0 & 6 bit symbol parity sum = 1 & 1 & 0 & 1 & 0 & 1 \\ 1 & 0 & 1 & 0 & 0 & 1 , & 1 & 0 & 1 & 1 & 0 & 1 , & 1 & 0 & 0 & 1 & 0 & 1 & 6 bit symbol parity sum = 1 & 0 & 0 & 0 & 0 & 1 \\ 1 & 0 & 0 & 1 & 0 & 0 , & 0 & 1 & 0 & 0 & 1 & 0 , & 1 & 1 & 1 & 1 & 0 & 0 & 6 bit symbol parity sum = 0 & 0 & 1 & 0 & 1 & 0 \\ 0 & 0 & 0 & 0 & 0 & 0 , & 1 & 0 & 1 & 0 & 1 & 1 , & 1 & 1 & 0 & 1 & 0 & 1 & 6 bit symbol parity sum = 0 & 1 & 1 & 1 & 1 & 0\end{matrix}$$

The overall net 6 bit symbol parity sum (that is the sum of the parity sums of each inner code codeword) is 0 0 0 0 0 0 and is present as the parity symbol in the outer code codeword.

In order to solve the parity check bits for the last inner code codeword the combined inner and outer code parity check matrix for this codeword needs to be in reduced echelon form. The reduced echelon form parity check matrix can straightforwardly be obtained by the standard Gauss elimination method.

In the corresponding decoder for the concatenated code, the inner code codewords are firstly decoded independently using a list decoder, such as a Dorsch decoder. For each inner code codeword, the outer code parity sum symbol is calculated. Taking the set of the most likely detected inner code codewords first, that is those with the highest correlation, a single codeword is systematically erased from the set together with its corresponding outer code parity sum symbol. This erased symbol, which is denoted as S(e) is calculated, using the properties of the outer code and the values of the inner code parity sum symbols from the non erased, detected inner code codewords. The highest correlation, inner code codeword with a parity sum symbol equal to S(e) is used to replace the erased codeword and the overall correlation with the received vector of this candidate concatenated codeword is calculated. The procedure is repeated with other inner code codewords being erased together with their corresponding outer code parity sum symbols to form other candidate, concatenated code, codewords. Finally the decoder outputs the concatenated codeword with the highest cross correlation with the received vector.

Consider the transmission of the concatenated codeword evaluated above:

$$\begin{matrix}0 & 1 & 0 & 1 & 0 & 1 & 0 & 1 & 0 & 0 & 0 & 0 & 1 & 1 & 0 & 0 & 0 & 0 \\ 1 & 0 & 1 & 0 & 0 & 1 & 1 & 0 & 1 & 1 & 0 & 1 & 1 & 0 & 0 & 1 & 0 & 1 \\ 1 & 0 & 0 & 1 & 0 & 0 & 0 & 1 & 0 & 0 & 1 & 0 & 1 & 1 & 1 & 1 & 0 & 0 \\ 0 & 0 & 0 & 0 & 0 & 0 & 1 & 0 & 1 & 0 & 1 & 1 & 1 & 1 & 0 & 1 & 0 & 1\end{matrix}$$

Before transmission the 0's are mapped to 1's and the 1's are mapped to −1's and transmitted over a Gaussian noise channel. Operating at an Eb/No of 3 dB the transmitted codewords are received as the noisy received vector having the values set out in Table 3 below.

TABLE 3
Received vector corresponding to transmitted concatenated code codeword

| | | | | | | | | | | | | | | | | | |
|---|---|---|---|---|---|---|---|---|---|---|---|---|---|---|---|---|---|
| 0.5 | −1.9 | 0.9 | −0.8 | 0.9 | −1.6 | 0.3 | −0.4 | 1.8 | 0.3 | 0.6 | 1.2 | −0.1 | −0.7 | 2.3 | 0.3 | −0.3 | 0.8 |
| −1.1 | 1.2 | −1.4 | 1.4 | 0.7 | −0.9 | −1.7 | 1.1 | 0.9 | −1.8 | −0.5 | −0.6 | 0.0 | 0.5 | 1.1 | −1.3 | 1.2 | −0.3 |
| −0.1 | −0.3 | 0.4 | −0.8 | 1.5 | 0.6 | 1.2 | −0.8 | −0.5 | 1.5 | −0.6 | 2.0 | −0.8 | −1.2 | 0.0 | 0.0 | 0.7 | −0.1 |
| 1.2 | 1.3 | −1.1 | 0.8 | 1.1 | 0.9 | −0.3 | −0.2 | −1.7 | 0.5 | −1.2 | −0.5 | −1.6 | −0.6 | 0.2 | 0.1 | 0.9 | −0.3 |

Each row of Table 3 corresponds to a transmitted inner code codeword.

The corresponding inner code codewords with the highest cross correlation are found using a list decoder. The 6 bit symbol parity sums are derived for each inner code codeword. The detected codewords together with their 6 bit symbol parity sums are shown below:

$$\begin{matrix}0 & 1 & 0 & 1 & 0 & 1 & 0 & 1 & 0 & 0 & 0 & 0 & 1 & 1 & 0 & 0 & 0 & 0 & 6 bit symbol parity sum = 1 & 1 & 0 & 1 & 0 & 1 \\ 1 & 0 & 1 & 0 & 0 & 1 & 1 & 0 & 1 & 1 & 0 & 1 & 1 & 0 & 0 & 1 & 0 & 1 & 6 bit symbol parity sum = 1 & 0 & 0 & 0 & 0 & 1 \\ 1 & 1 & 1 & 1 & 0 & 0 & 0 & 1 & 1 & 0 & 1 & 0 & 1 & 1 & 0 & 0 & 0 & 1 & 6 bit symbol parity sum = 0 & 0 & 1 & 1 & 1 & 1 \\ 0 & 0 & 0 & 0 & 0 & 0 & 1 & 0 & 1 & 0 & 1 & 1 & 1 & 1 & 0 & 1 & 0 & 1 & 6 bit symbol parity sum = 0 & 1 & 1 & 1 & 1 & 0\end{matrix}$$

The overall 6 bit symbol parity sum is 0 1 1 1 0 1 and is present as the parity symbol in the outer code.

As with the earlier examples above, all of the detected inner code codewords are correct except for the third codeword. This is apparent from the properties of the outer code because the overall 6 bit parity sum is not zero. Thus the detected four inner code codewords are not a codeword of the concatenated code and could not have been transmitted.

Erasing the third codeword, and deriving the 6 bit symbol parity sum from the other codewords gives the 6 bit symbol parity sum equal to:

110101 plus 100001 plus 011110=001010.

Thus the third inner code codeword should have a 6 bit symbol parity sum equal to 001010. From the output of the list decoder for the inner code with received vector as input (that is the values in row 3 of Table 3) it is found that the codeword with the highest correlation and having a 6 bit symbol parity sum equally to 0 0 1 0 1 0 is as follows:

1 0 0 1 0 0 0 1 0 0 1 0 1 1 1 1 0 0

The candidate concatenated code codeword thus generated becomes:

$$\begin{matrix}0 & 1 & 0 & 1 & 0 & 1 & 0 & 1 & 0 & 0 & 0 & 0 & 1 & 1 & 0 & 0 & 0 & 0 \\ 1 & 0 & 1 & 0 & 0 & 1 & 1 & 0 & 1 & 1 & 0 & 1 & 1 & 0 & 0 & 1 & 0 & 1 \\ 1 & 0 & 0 & 1 & 0 & 0 & 0 & 1 & 0 & 0 & 1 & 0 & 1 & 1 & 1 & 1 & 0 & 0 \\ 0 & 0 & 0 & 0 & 0 & 0 & 1 & 0 & 1 & 0 & 1 & 1 & 1 & 1 & 0 & 1 & 0 & 1\end{matrix}$$

This concatenated codeword has a cross correlation of 53.0 with the entire received vector given in Table 3. Following the procedure of erasing other inner code codewords and producing other candidate concatenated codewords it is found that the highest cross correlation value is indeed 53.0 and the following candidate concatenated codeword is output from the decoder:

$$\begin{matrix}0 & 1 & 0 & 1 & 0 & 1 & 0 & 1 & 0 & 0 & 0 & 0 & 1 & 1 & 0 & 0 & 0 & 0 \\ 1 & 0 & 1 & 0 & 0 & 1 & 1 & 0 & 1 & 1 & 0 & 1 & 1 & 0 & 0 & 1 & 0 & 1 \\ 1 & 0 & 0 & 1 & 0 & 0 & 0 & 1 & 0 & 0 & 1 & 0 & 1 & 1 & 1 & 1 & 0 & 0 \\ 0 & 0 & 0 & 0 & 0 & 0 & 1 & 0 & 1 & 0 & 1 & 1 & 1 & 1 & 0 & 1 & 0 & 1\end{matrix}$$

In the case where the length of the inner code is not equal to an integral multiple of outer code symbols the inner code codewords may be extended with dummy 0's that are not actually transmitted. For example if the outer code uses 10 bit symbols and the inner code is of length 128 bits then two 0's are appended to each inner code codeword and used in calculating the outer code symbol parity sum for that codeword, so that each inner code codeword is considered to be composed of 13 symbols with each symbol consisting of 10 bits. After transmission of the 128 bit inner code codeword and detection using the list decoder, the two 0's are appended and the outer code symbol parity sum for the appended codeword calculated.

### Example 5

An example of the performance of the embodiment of the invention of Example 4 is shown in FIG. 6. The outer code is a (32,31,2) code and consists of 16 bit symbols and a codeword length of 32 symbols. The inner code is a (128,68,16) code and forms an overall (512,256,32) concatenated code. Each inner code codeword consists of 8 symbols from the outer code codeword. FIG. 6 shows the output detected concatenated codeword error rate (FER) plotted as a function of signal power to noise power in terms of the ratio of the energy per information bit to the noise spectral density (Eb/No). Also shown in FIG. 6 is the performance of other code/decoder combinations that represent the current state of the art, an LDPC code with Belief Propagation decoding, a Turbo code with iterative decoding, and a convolutional code with Viterbi decoding. Optimised codes have been used throughout with results obtained by computer simulations.

It can be seen that the method of the present invention exhibits significantly better performance particularly at low error rates compared to the current state of the art methods.

1. A method of processing a received concatenated code codeword, the concatenated code codeword comprising a plurality of inner code codewords and one or more outer code codewords, each inner code codeword comprising one or more information or parity symbols, each outer code codeword comprising one or more information symbols and one or more parity symbols that correspond to the symbols of the inner code codewords, the method comprising:
(i) decoding the inner code codewords from the received concatenated code codeword;
(ii) erasing a subset of the received inner code codewords according to the correspondence between the symbols of each outer code codeword and the symbols of the inner code codewords; and
(iii) determining a replacement inner code codeword to replace each of the erased inner code codewords to provide a first candidate concatenated code codeword.

2. The method of claim 1, further comprising:
(iv) erasing a different subset of the received inner code codewords according to the correspondence between the symbols of each outer code codeword and the symbols of the inner code codewords;
(v) determining further replacement inner code codewords to replace each of the different subset of erased inner code codewords to provide a second candidate concatenated code codeword; and
(vi) determining the candidate concatenated code codeword having the highest correlation with the decoded concatenated code codeword.

3. The method of claim 2, wherein each inner code codeword comprises a plurality of symbols from the outer code.

4. The method of claim 3, wherein each inner code codeword comprises one or more data symbols and at least one parity symbol from the outer code.

5. The method of claim 2, wherein the concatenated codeword comprises a plurality of outer code codewords.

6. The method of claim 5, wherein the outer code codeword comprises symbols containing different numbers of bits.

7. The method of claim 2, wherein the correspondence between symbols of the inner code codewords and the parity symbols of each outer code codeword is a sum.

8. The method of claim 7, wherein each inner code codeword is represented as a sum parity symbol that is the sum of the symbols of the inner code codeword.

9. The method of claim 8, wherein each parity symbol in each outer code codeword is a sum of the sum parity symbols representing each inner code codeword.

10. The method of claim 2, wherein all the unambiguous erasure patterns of the inner code codewords are employed and a candidate concatenated code codeword generated for each erasure pattern, each candidate concatenated code codewords being correlated for reliability with the received vector.

11. The method of claim 2, wherein less than all the erasure patterns for the inner code codewords are applied.

12. The method of claim 11, wherein the inner code codewords are correlated for reliability with the received vector and ranked for reliability.

13. The method of claim 12, wherein only those erasure patterns involving inner code codewords having a reliability below a predetermined threshold level are applied.

14. The method of claim 13, wherein each candidate concatenated code codeword is correlated for reliability with the received vector of the transmitted concatenated code codeword, the correlation for reliability being carried out using information already obtained regarding the reliability of replacement inner code codewords comprised in the candidate concatenated code codeword.

15. The method of claim 2, wherein one or more dummy zero bits are appended to each received inner code codeword in the case that the length in bits of the inner codes is not equal to an integral multiple of symbols of the outer code codeword.

16. A concatenated code codeword encoded on a computer readable medium comprising a plurality of inner code codewords and one or more outer code codewords, each inner code codeword comprising at least one information symbol or parity symbol from the outer code.

17. The concatenated code codeword of claim 16, wherein each inner code codeword comprises a plurality of symbols of the outer code.

18. The concatenated code codeword of claim 17, wherein each inner code codeword comprises one or more data symbols and at least one parity symbol of the outer code.

19. The concatenated code codeword of claim 18, wherein each outer code codeword comprises a plurality of information and parity symbols.

20. The concatenated code codeword of claim 19, wherein each outer code codeword comprises one or more data symbols.

21. The concatenated code codeword of claim 20, wherein the relationship between the symbols of the inner code codewords and the parity symbols of each outer code codeword is a weighted sum according to the parity check equations of the outer code.

22. The concatenated code codeword of claim 21, wherein each inner code codeword is represented as a sum parity symbol that is the sum of the symbols of the inner code codeword.

23. The concatenated code codeword of claim 22, wherein each parity symbol in each outer code codeword is a sum of the sum parity symbols representing each of the inner code codewords contained in the weighted sum according to the parity check equations of the outer code.

24. (canceled)

25. A system for decoding a concatenated code codeword, the concatenated code codeword comprising a plurality of inner code codewords and one or more outer code codewords, each inner code codeword comprising one or more information or parity symbols, each outer code codeword comprising one or more information symbols and one or more parity symbols that correspond to the symbols of the inner code codewords, the system comprising:
(i) means for decoding the received concatenated code codeword;
(ii) means for erasing a subset of the received inner code codewords according to the correspondence between the information and parity symbols of each outer code codeword and the information and parity symbols of the inner code codewords; and
(iii) means for determining a replacement inner code codeword to replace each of the erased inner code codewords to provide a first candidate concatenated code codeword.

26. The system according to claim 25, further comprising:
(iv) means for erasing a different subset of the received inner code codewords according to the said correspondence between the symbols of each outer code codeword and the symbols of the inner code codewords;
(v) means for determining further replacement inner code codewords to replace each of the thus different subset of erased inner code codewords to provide a second candidate concatenated code codeword; and
(vi) means for determining the candidate concatenated code codeword having the highest correlation with the decoded concatenated code codeword.

27. (canceled)
